(19) United States
(12) Patent Application Publication
(10) Pub. No.: US 2012/0286635 A1
(43) Pub. Date: Nov. 15, 2012

(54) COMPUTER CASE

(75) Inventor: Jo-Chiao WANG, Taipei Hsien (TW)

(73) Assignee: AOpen Inc., Taipei Hsien (TW)

(21) Appl. No.: 13/275,050

(22) Filed: Oct. 17, 2011

(30) Foreign Application Priority Data
May 13, 2011 (TW) 100208608

(51) Int. Cl. H05K 5/03; H05K 7/20; H05K 5/02

(52) U.S. Cl. 312/236; 312/223.2

(57) ABSTRACT

The present invention relates to a computer case, which comprises a case body and a carrier. The case body is used for installing a motherboard; the carrier is disposed in the case body for installing a plurality of first pieces of hardware. The plurality of first pieces of hardware are connected electrically to the motherboard. In addition, at least a first hardware of the plurality of first pieces of hardware can be replaced by a second piece of hardware, which is connected electrically to the motherboard. The computer case according to the present invention includes the carrier for installing and replacing a plurality of pieces of hardware according to users' requirements and forming various hardware combinations. Thereby, waste of space in the computer case can be avoided.

### FIELD OF THE INVENTION

The present invention relates generally to a computer case, and particularly to a computer case capable of installing various hardware combinations.

### BACKGROUND OF THE INVENTION

The development trend of current computer cases is towards smaller sizes. For small-sized computer cases, due to spatial limitations, the motherboard is usually disposed at a single corner; the major components, such as CPU, power supply, hard disk, heat sink, and interface cards, are disposed at fixed locations and connected with the motherboard. It is thereby known from the above that the components inside a computer case according to prior art are disposed at fixed locations. Consequently, after a component is disassembled, another component cannot be disposed at the same location, leasing to waste of space in the computer case. Because no expansion space is available in a small-sized computer case, users cannot add components into the computer case according to their needs. If other components are to be added, it is necessary to replace the computer case, and hence bringing inconvenience in usage.

Accordingly, the present invention provides a computer case, which is capable of forming various hardware combinations according to users' requirements without replacing the computer case. Besides, the present invention also avoids waste of space in the computer case.

### SUMMARY

An objective of the present invention is to provide a computer case, which includes a carrier for installing and replacing a plurality of pieces of hardware according to users' requirements and forming various hardware combinations. Thereby, waste of space in the computer case can be avoided.

Another objective of the present invention is to provide a computer case. The plurality of pieces of hardware are disposed on the carrier for compressing the volume of the plurality of pieces of hardware disposed in the computer case and hence miniaturizing the computer case.

For achieving the objectives described above, the present invention provides a computer case, which comprises a case body for installing a motherboard and a carrier disposed in the case body for installing a plurality of first pieces of hardware. The plurality of first pieces of hardware are connected electrically to the motherboard. In addition, at least a first hardware of the plurality of first pieces of hardware can be replaced by a second piece of hardware, which is connected electrically to the motherboard.

### BRIEF DESCRIPTION OF THE DRAWINGS

FIG. 1 shows a schematic diagram of assembly according a preferred embodiment of the present invention;

FIG. 2 shows another schematic diagram of assembly according a preferred embodiment of the present invention;

FIG. 3 shows a structural schematic diagram according a preferred embodiment of the present invention;

FIG. 4 shows a partial cross-sectional view according a preferred embodiment of the present invention;

FIG. 5 shows a schematic diagram of assembly according another preferred embodiment of the present invention;

FIG. 6 shows a schematic diagram of assembly according another preferred embodiment of the present invention;

FIG. 7 shows a structural schematic diagram according another preferred embodiment of the present invention; and

FIG. 8 shows a structural schematic diagram according another preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

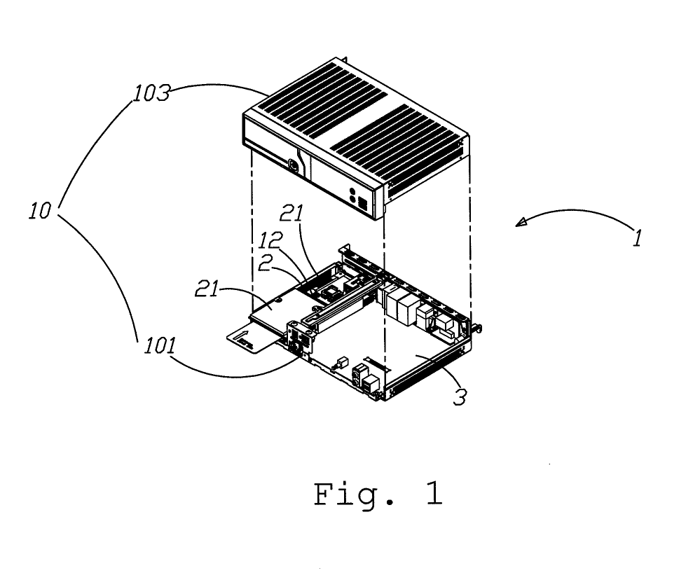

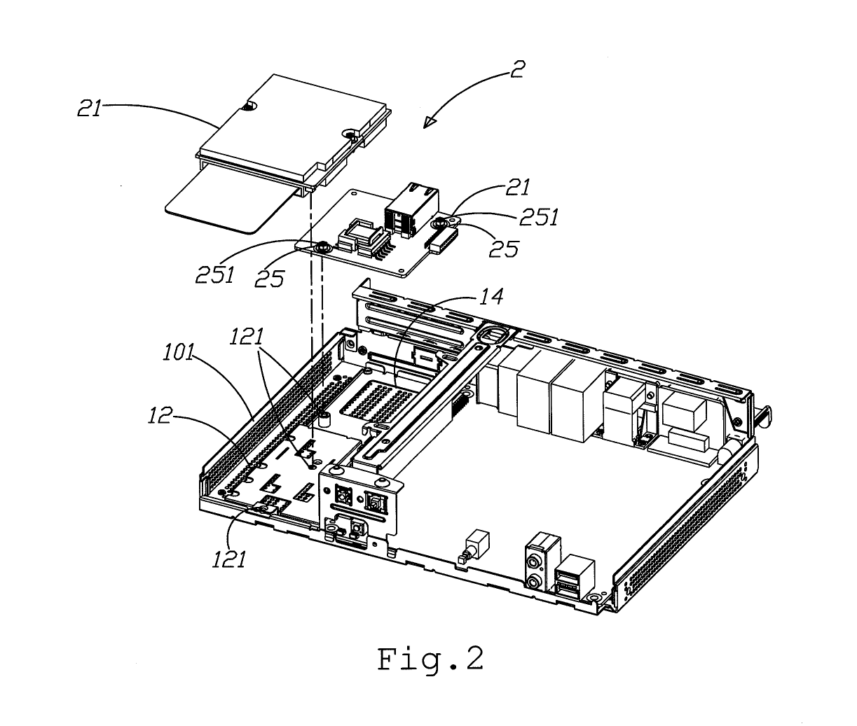

FIG. 1 and FIG. 2 show schematic diagrams of assembly according a preferred embodiment of the present invention. As shown in the figure, the present invention provides a computer case 1 for installing a plurality of pieces of hardware 2, which include a plurality of first pieces of hardware 21 and a second piece of hardware 23. The plurality of pieces of hardware 2 are not installed in the computer case 1 altogether. Instead, they are installed according to users' requirements. The computer case 1 comprises a case body 10 and a carrier 12. The case body includes 10 a bottom cover 101 and a top cover 103. The carrier 12 is disposed on the bottom cover 101. According to the present embodiment, the plurality of first pieces of hardware 21 are disposed on the carrier 12. Hence, the bottom cover 101 accommodates the plurality of first pieces of hardware 21. A motherboard 3 is disposed on the bottom cover 101 and is located below the carrier 12. The plurality of first pieces of hardware 21 and the motherboard 3 are connected electrically. A processor (not shown in the figures) on the motherboard 3 controls the plurality of first pieces of hardware 21. Finally, the top cover 103 is disposed on the bottom cover 101 for covering the protecting the plurality of first pieces of hardware 21 and the motherboard 3. The plurality of first pieces of hardware 21 according to the present embodiment include a card reader and a network card. Nonetheless, the types of the first pieces of hardware 21 are not limited to card readers or network cards.

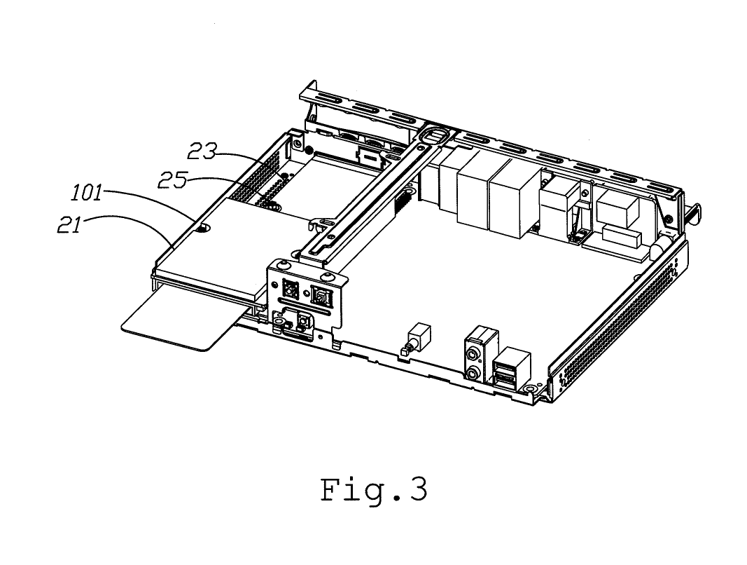

FIG. 3 shows a structural schematic diagram according a preferred embodiment of the present invention. As shown in the figure, a first hardware 21 of the plurality of first pieces of hardware 21 can be replaced by the second piece of hardware 23 according to users' requirements. For example, according to the present embodiment, the network card (the first hardware 21) is disassembled and a POE interface card (the second piece of hardware 23) is replaced. The present embodiment is only a preferred embodiment of the present invention. The present invention is not limited to the embodiment.

The method for replacing the first hardware 21 by the second piece of hardware 23 described above is first to disassemble the first hardware 21 from the carrier 12. Then install the second piece of hardware 23 on the carrier 12 and at the location from where the first hardware 21 is disassembled. Referring again to FIG. 2, the reason why the first and the second pieces of hardware 21, 23 are interchangeable is mainly because the carrier 12 has a plurality of fixing hole 121. The plurality of first pieces of hardware 21 and the second piece of hardware 23 has a plurality of fixing parts 25, respectively. The plurality of fixing holes 121 correspond to the plurality of fixing parts 25. Thereby, when the plurality of first hardware 21 and the second piece of hardware 23 are disposed on the carrier 12, the plurality of fixing parts 25 of the plurality of first pieces of hardware 21 and the second piece of hardware 23 are disposed on the corresponding plurality of fixing holes 121 for fixing the plurality of first pieces of hardware 21 and the second piece of hardware 23 on the carrier 12.

When the plurality of fixing parts 25 of the second piece of hardware 23 corresponds to the plurality of fixing parts 25 of the first hardware 21, the plurality of fixing parts 25 of the second piece of hardware 23 corresponds to the plurality of fixing holes 121, just like the correspondence of the plurality of fixing parts 25 of the first hardware 21 to the plurality of fixing holes 121. Thereby, it is not necessary to dispose the plurality of fixing holes 121 corresponding to the plurality of fixing parts 25 of the second piece of hardware 23. The plurality of fixing parts 25 of the second piece of hardware 23 (POE interface card) according to the present embodiment correspond to the plurality of fixing parts 25 of the first hardware 21 (network card). Consequently, the plurality of fixing parts 25 of the second piece of hardware 23 can be disposed to the plurality of fixing holes 121 to which the plurality of fixing parts 25 of the first hardware are disposed originally.

In addition, when the plurality of fixing parts 25 of the second piece of hardware 23 does not correspond to the plurality of fixing parts 25 of the first hardware 21, the carrier 12 has disposed the plurality of fixing holes 121 corresponding to the plurality of fixing parts 25 of the second piece of hardware 23 when the carrier 12 was manufactured. Although the second piece of hardware 23 and the first hardware 21 are fixed at the same location on the carrier 12, the carrier 12 already has the plurality of fixing holes 121 corresponding to the plurality of fixing parts 25 of the second piece of hardware 23, making the plurality of fixing parts 25 of the second piece of hardware 23 fixed in the plurality of fixing holes 121. Thereby, even the first hardware 21 and the second piece of hardware 23 have different fixing parts 25, they still are interchangeable on the carrier 12 with ease.

Each fixing part 25 described above includes a fixing member 251. When the first hardware 21 or the second piece of hardware 23 is fixed on the carrier 12, the fixing member 251 of the fixing part 25 is fixed to the corresponding fixing hole 121.

Refer again to FIG. 2. The computer case according to the present embodiment provides the carrier 12, which can carry various pieces of hardware 2 because the carrier 12 has the plurality of fixing holes 121 for installing the pieces of hardware 2. Besides, because the plurality of fixing parts 25 of the pieces of hardware 2 are fixed on the carrier 12 and the fixing parts 25 are slightly projecting from the carrier 12, preserved space 14 between a surface of the carrier 12 without the plurality of pieces of hardware 2 and the bottom cover 101 is reserved. Thereby, the fixing part 25 will not be obstructed by the bottom cover 101, which obstruction may cause the fixing part 25 unable to be fixed on the carrier 12. The preserved space 14 between the carrier 12 and the bottom cover 101 also provides the plurality of pieces of hardware 2 with space for heat dissipation. Thereby, overheating of the plurality of pieces of hardware 2, which may lead to damages of the plurality of pieces of hardware 2, can be prevented. The plurality of pieces of hardware 2 has a connection circuit stuffed in the preserved space 14 and hence installation of the plurality of pieces of hardware 2 will not be affected.

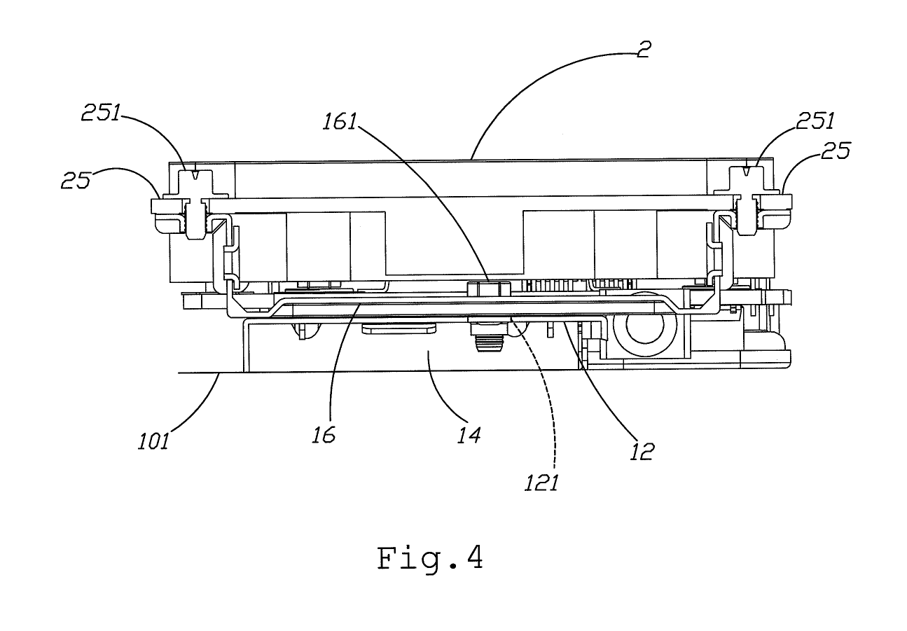

FIG. 4 shows a partial cross-sectional view according a preferred embodiment of the present invention. As shown in the figure, when the hardware 2 cannot be disposed directly on the carrier 12, the hardware 2 can be fixed on the carrier 12 via a connecting frame 16. For example, the card reader (the hardware 2) can be disposed on the carrier 12 via the connecting frame 16. The connecting frame 16 has at least a connecting part 161, which is disposed in the fixing hole 121 of the carrier 12 for fixing the connecting frame 16 on the carrier 12. The fixing hole 121 corresponding to the connecting part 161 described above is disposed while manufacturing the carrier 121 beforehand. The connecting frame 16 has two fixing holes 163. The two fixing members 251 of the two fixing parts 25 of the hardware 21 are disposed in the two fixing holes 163 for fixing the hardware 2 on the connecting frame 16. Thereby, the hardware 2 is fixed on the carrier 12 via the connecting frame 16.

The connecting frame 16 described above is mainly applied for the pieces of hardware 2 unable to be disposed directly on the carrier 12. The plurality of pieces of hardware 2 are expected to be used by the users. Thereby, the carrier 12 will have the plurality of fixing holes 121 corresponding to the plurality of fixing parts 25 of the plurality of pieces of hardware 2 and the connecting parts 161 of the connecting frame 16. If a third hardware unexpected by the user is to be installed, it can be disposed on the carrier 12 via the connecting frame 16. It is not necessary to dispose additional plurality of fixing holes 121 on the carrier 12.

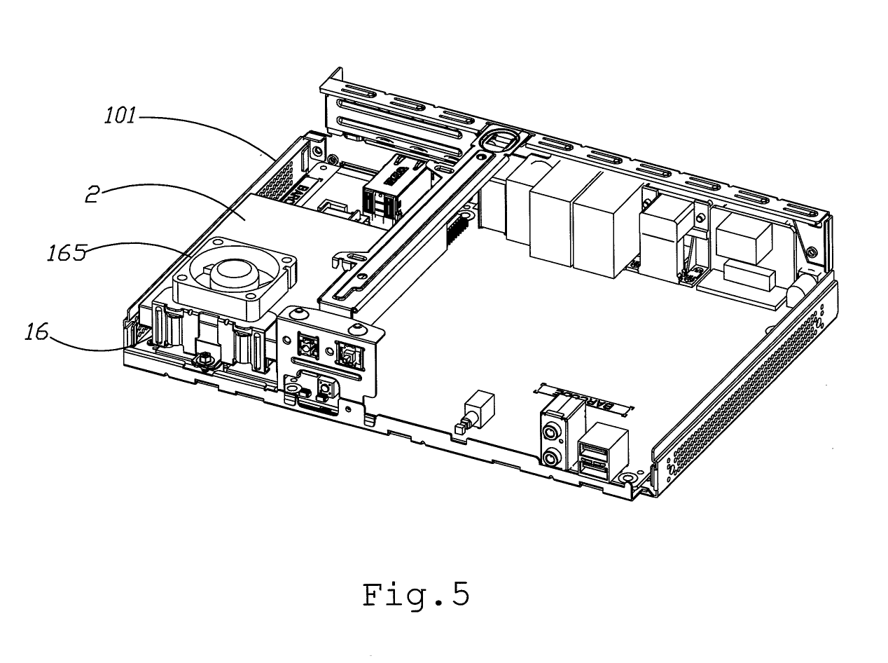

FIG. 5 shows a schematic diagram of assembly according another preferred embodiment of the present invention. As shown in the figure, the connecting frame 16 according to the present embodiment further has a heat-dissipating device 165, which can be a fan or a heat-dissipating fin. According to the present embodiment, the heat-dissipating device 165 is a fan. The hardware 2 (for example, a hard disk) disposed on the connecting frame 16 according to the present embodiment may produce a great deal of heat after long-term operations. Thereby, the heat-dissipating device 165 disposed on the connecting frame 16 can dissipate heat for the hardware 2 and hence reducing its temperature effectively.

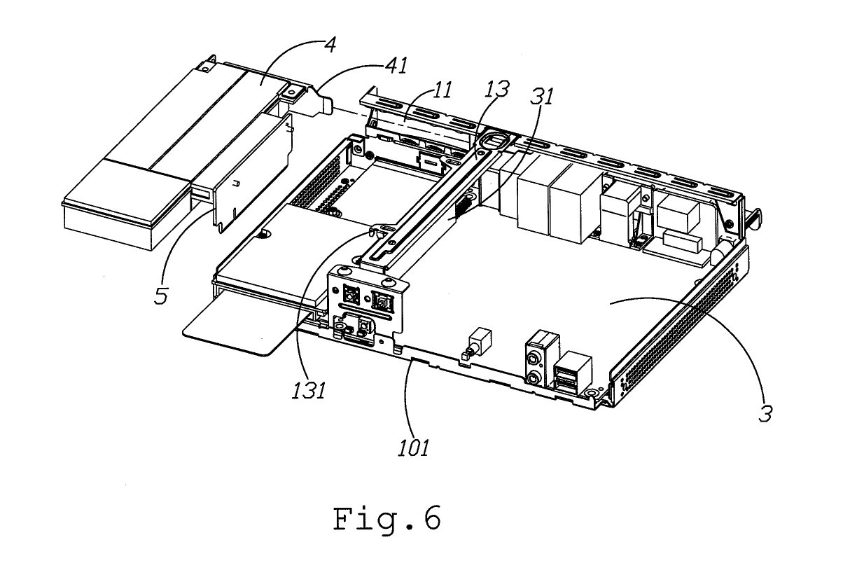

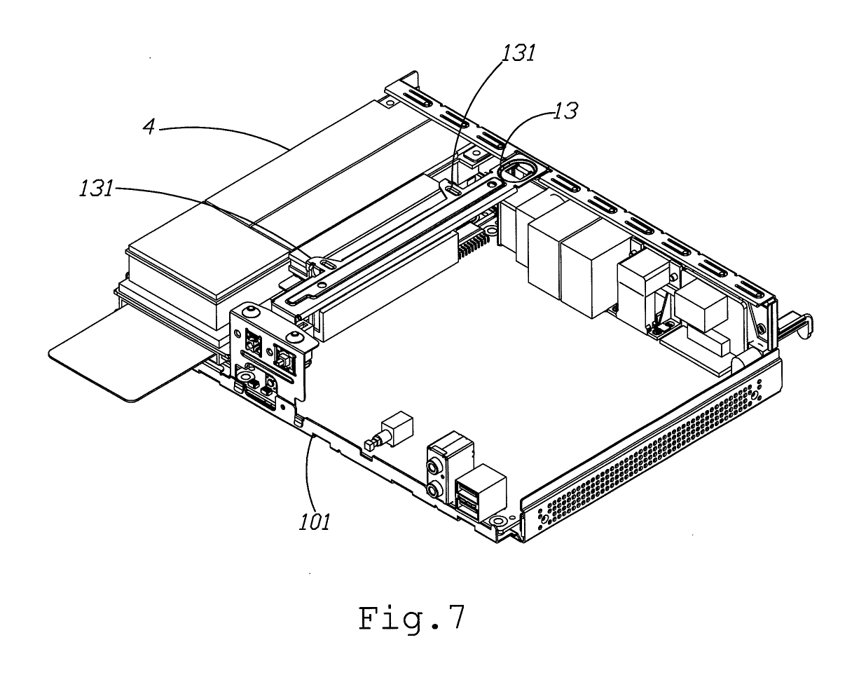

FIG. 6 and FIG. 7 show a schematic diagram of assembly and a structural schematic diagram according another preferred embodiment of the present invention. As shown in the figures, the bottom cover 101 according to the present embodiment further includes an expansion slot 11 for an interface card 4, such as a display card. The interface card 4 according to the present embodiment has an inserting member 41, which inserts to the expansion slot 11. The interface card 4 inserts to a socket 31 of the motherboard 3 via a conversion card 5 at the bottom of the interface card 4 for connecting electrically the interface card 4 with the motherboard 5. For improving the installation stability of the interface card 4, the computer case further has a support member 13 disposed on the bottom cover 101. The support member 13 crosses the motherboard 3 of the bottom cover 101 and is located below the interface card 4 for supporting the interface card 4. The support member 13 further has at least a protruding pillar 131 for support the interface card 4.

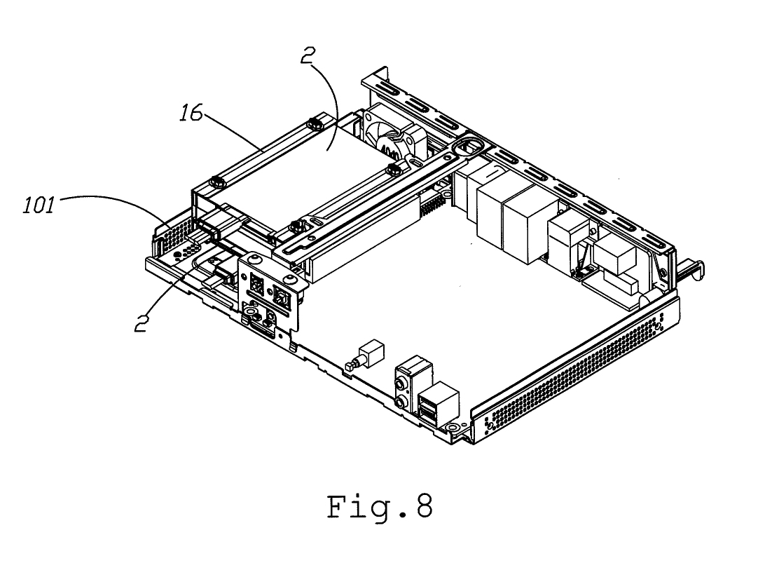

FIG. 8 shows a structural schematic diagram according another preferred embodiment of the present invention. As shown in the figure, according to the present embodiment, the carrier can be drawn out and two pieces of hardware 2 can be disposed on the connecting frame 16. Then the connecting frame 16 can be disposed directly on the bottom cover 101. Thereby, the users can apply the carrier and the connecting frame 16 flexibly and thus forming various hardware combinations in the computer case.

To sum up, the present invention provides a computer case, which includes a carrier for installing and replacing a plurality of pieces of hardware according to users' requirements and forming various hardware combinations. Thereby, waste of space in the computer case can be avoided. When the pieces of hardware are disposed on the carrier, the volume of the plurality of pieces of hardware disposed in the computer case is compressed and hence miniaturizing the computer case.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A computer case, comprising:
a case body, for disposing a motherboard; and
a carrier, disposed in said case body, for disposing a plurality of first pieces of hardware connected electrically to said motherboard;
where at least a first hardware of said plurality of first pieces of hardware can be replaced by at least a second piece of hardware connected electrically to said motherboard.

2. The computer case of claim 1, wherein said carrier has a plurality of fixing holes; said plurality of first pieces of hardware and said second piece of hardware have a plurality of fixing parts, respectively; and said plurality of fixing parts are fixed to said corresponding plurality of fixing holes.

3. The computer case of claim 2, wherein each of said plurality of fixing parts includes a fixing member disposed in said corresponding fixing hole, respectively.

4. The computer case of claim 1, and further comprising at least a connecting frame, disposed on said carrier, said first hardware or said second piece of hardware disposed on said connecting frame, and fixing said first hardware or said second piece of hardware on said carrier.

5. The computer case of claim 4, wherein said connecting frame includes at least a connecting part disposed on said carrier.

6. The computer case of claim 4, wherein said connecting frame at least a fixing hole for fixing said first hardware or said second piece of hardware.

7. The computer case of claim 4, and further comprising a heat-dissipating device, disposed on said connecting frame, and corresponding to said first hardware or said second piece of hardware.

8. The computer case of claim 7, wherein said heat-dissipating device is a fan.

9. The computer case of claim 1, wherein said case body includes:
a bottom cover, disposing said motherboard and said carrier, and accommodating said plurality of first pieces of hardware and said second piece of hardware; and
a top cover, disposed on said bottom cover, covering said motherboard, said plurality of first pieces of hardware, and said second piece of hardware.

10. The computer case of claim 1, wherein said case body includes an expansion slot for an interface card to insert to, where said interface card corresponds to said carrier.

11. The computer case of claim 10, wherein said interface card has an inserting member inserting to said expansion slot.

12. The computer case of claim 10, and further comprising a support member, disposed on said case body, and supporting said interface card.

13. The computer case of claim 12, wherein said support member has at least a protruding pillar for supporting said interface card.
